(19) United States
(12) Patent Application Publication
(10) Pub. No.: US 2025/0168996 A1
(43) Pub. Date: May 22, 2025

(54) FLEXIBLE DISPLAY MODULE AND ELECTRONIC DEVICE

(71) Applicant: Wuhan China Star Optoelectronics Semiconductor Display Technology Co., Ltd., Wuhan (CN)

(72) Inventor: Chengjie JIA, Wuhan (CN)

(21) Appl. No.: 17/793,420

(22) PCT Filed: Jun. 30, 2022
(86) PCT No.: PCT/CN2022/103053

§ 371 Date: Jan. 28, 2025

(30) Foreign Application Priority Data
Jun. 10, 2022 (CN) 202210658192.X

(51) Int. Cl. H05K 5/02; B65H 75/44; B65H 75/48

(52) U.S. Cl. CPC H05K 5/0217; B65H 75/4486; B65H 75/486

(57) ABSTRACT

A flexible display module and an electronic device are provided. The flexible display module includes a fixing bracket; a rolling unit disposed on the fixing bracket. The rolling unit includes at least two rolling elements, axial directions of the at least two rolling elements are parallel to each other, and the at least two rolling elements are arranged in sequence along the axial directions, each of the rolling elements is rotatably connected to the fixing bracket, and both ends of each of the rolling elements are supported on the fixing bracket.

### FIELD OF INVENTION

The present application relates to the field of display, and in particular, to a flexible display module and an electronic device.

### DESCRIPTION OF PRIOR ART

With the development of flexible screens, from folding screens to sliding screens, it is all to achieve a larger screen display ratio for smaller personal terminals. In smaller personal terminals, it is obvious that a screen-to-casing ratio of the sliding screen is higher than that of the folding screen, and personal terminal is more compact.

The sliding screen includes an expanded state and a contracted state. In the expanded state, part of the flexible display panel stored in a casing is drawn out after passing through a roller to increase the display area; and in the contracted state, an exposed part of the flexible display panel is then stored back into the casing through the roller to reduce the display area and facilitate user portability. The flexible display panel includes a plurality of bendable flexible layers so as to facilitate the winding of the flexible display panel. When the sliding screen is in an expanded or contracted state for a long time, portions of the flexible display panel corresponding to the roller and other winding parts are prone to curl marks. In order to eliminate the curl marks faster, in the process of assembling the flexible display panel and the terminal, an initial tensile force will be applied to the flexible display panel to tension the flexible display panel, and during the process that the sliding screen switches between the expanded state and the contracted state, the curl marks of the flexible display panel can be eliminated.

During research and practice of the prior art, the inventors of the present application found that the initial tension applied to the flexible display panel easily leads to a deformation of the roller, and especially a deformation of a suspended part in a middle of the roller is particularly serious, which can cause the roller to not rotate smoothly, resulting in jamming, which in turn leads to increased sliding load.

### SUMMARY

### Technical Problem

Embodiments of the present application provide a flexible display module and an electronic device, which can solve the technical problem that the roller of the sliding screen is easily deformed to cause sliding load.

### Solution of Problem

### Technical Solution

An embodiment of the present application provides a flexible display module, including:
a fixing bracket;
a middle frame bracket slidably connected to the fixing bracket;
a rolling unit disposed on the fixing bracket, wherein the rolling unit includes at least two rolling elements, axial directions of the at least two rolling elements are parallel to each other, and the at least two rolling elements are arranged in sequence along the axial directions, each of the rolling elements is rotatably connected to the fixing bracket, and both ends of each of the rolling elements are supported on the fixing bracket;
a flexible display panel, wherein a first end of the flexible display panel is fixedly connected to the middle frame bracket, and the flexible display panel is partially supported on the rolling elements; and
a winding mechanism, wherein a second end of the flexible display panel is connected to the winding mechanism, and the winding mechanism is configured to wind the flexible display panel.

Optionally, in some embodiments of the present application, the at least two rolling elements are disposed coaxially.

Optionally, in some embodiments of the present application, the rolling unit further includes a plurality of rotating shafts and a plurality of supporting rotating elements, an axial direction of the rotating shafts and an axial direction of the supporting rotating elements are parallel to the axial directions of the rolling elements; the plurality of rotating shafts are arranged in sequence along the axial direction of the rotating shafts, the rotating shafts are fixed to the rolling elements; the plurality of supporting rotating elements are sequentially arranged along the axial direction of the supporting rotating elements, each of the supporting rotating elements is sleeved outside one of the rotating shafts, each of the supporting rotating elements is disposed on the fixing bracket, and the rotating shafts is rotatably connected to the fixing bracket through the supporting rotating elements.

Optionally, in some embodiments of the present application, the fixing bracket is provided with a mounting seat, the mounting seat is provided with a mounting hole, and each of the supporting rotating elements is mounted in the mounting hole.

Optionally, in some embodiments of the present application, the mounting seat is further provided with a notch, and the notch communicates with the mounting hole.

Optionally, in some embodiments of the present application, a width of the notch is smaller than a diameter of the mounting hole.

Optionally, in some embodiments of the present application, the at least two rolling elements rotate synchronously.

Optionally, in some embodiments of the present application, adjacent ones of the rolling elements are fixedly connected to a same one of the rotating shafts.

Optionally, in some embodiments of the present application, the at least two rolling elements are capable of rotating independently.

Optionally, in some embodiments of the present application, the at least two rolling elements are respectively fixedly connected to different rotating shafts, and the rotating shafts are in one-to-one correspondence to the supporting rotating elements, and each of the rolling elements is rotatably connected to the fixing bracket through a corresponding one of the rotating shafts and a corresponding one of the supporting rotating elements.

Optionally, in some embodiments of the present application, the fixing bracket includes two first sidewalls, a second sidewall, and a first bottom wall, opposite sides of the first bottom wall are respectively connected to the first sidewalls, one end of the first bottom wall is connected to the second sidewall, one end of the second sidewall is connected to one of the first sidewalls, and another end of the second sidewall is connected to another one of the first sidewalls, and the two first sidewalls, the second sidewall, and the first bottom wall are jointly enclosed to form a first accommodating space.

Optionally, in some embodiments of the present application, the middle frame bracket includes two third sidewalls, a fourth sidewall, and a second bottom wall, opposite sides of the second bottom wall are respectively is connected to the third sidewalls, one end of the second bottom wall is connected to the fourth sidewall, one end of the fourth sidewall is connected to one of the third sidewalls, another end of the fourth sidewall is connected to another one of the third sidewalls, and the two third sidewalls, the fourth sidewall, and the second bottom wall are jointly enclosed to form a second accommodating space; and

wherein the two first sidewalls are located between the two third sidewalls, the fourth sidewall and the second sidewall are arranged opposite to each other, and the second accommodating space communicates with the first accommodating space.

Optionally, in some embodiments of the present application, a fixing portion is protruded from the second bottom wall, and the first end of the flexible display panel is mounted on the fixing portion.

Optionally, in some embodiments of the present application, the second bottom wall is further provided with a support portion, and the flexible display panel is supported on the support portion.

Optionally, in some embodiments of the present application, a plurality of gear teeth are arranged on circumferential surfaces of the rolling elements, a back of the flexible display panel is provided with a rack, and the gear teeth are engaged and connected to the rack.

Embodiments of the present application further provide an electronic device including the above-mentioned flexible display module.

Optionally, in some embodiments of the present application, the at least two rolling elements are disposed coaxially.

Optionally, in some embodiments of the present application, the rolling unit further includes a plurality of rotating shafts and a plurality of supporting rotating elements, an axial direction of the rotating shafts and an axial direction of the supporting rotating elements are parallel to the axial directions of the rolling elements; the plurality of rotating shafts are arranged in sequence along the axial direction of the rotating shafts, the rotating shafts are fixed to the rolling elements; the plurality of supporting rotating elements are sequentially arranged along the axial direction of the supporting rotating elements, each of the supporting rotating elements is sleeved on an outside of one of the rotating shafts, each of the supporting rotating elements is disposed on the fixing bracket, and the rotating shafts is rotatably connected to the fixing bracket through the supporting rotating elements.

Optionally, in some embodiments of the present application, the fixing bracket is provided with a mounting seat, the mounting seat is provided with a mounting hole, and each of the supporting rotating elements is mounted in the mounting hole.

Optionally, in some embodiments of the present application, the mounting seat is further provided with a notch, and the notch communicates with the mounting hole.

Embodiments of the present application adopt a flexible display module and an electronic device. The multi-segment rolling elements are adopted to replace rollers to support the flexible display panel. Since a length of the rolling elements is less than a length of the roller, and the two ends of each segment of the rolling elements are supported on the fixing bracket, the rolling elements are evenly stressed, the supporting strength is higher, and the rolling elements are not easily deformed. As such, there is no jamming when the rolling elements rotate, effectively reducing the sliding load of the middle frame bracket relative to the fixing bracket.

### Beneficial Effect of Invention Beneficial Effect

Embodiments of the present application adopt a flexible display module and an electronic device. By adopting multi-segment rolling elements to replace the rollers to support the flexible display panel. Since a length of the rolling elements is less than a length of the roller, and the two ends of each segment of the rolling elements are supported on the fixing bracket, the above-mentioned rolling elements are evenly stressed, the supporting strength is higher, and the rolling elements is not easily deformed. As such, there is no jamming when the rolling elements rotates, effectively reducing the sliding load of the middle frame bracket relative to the fixing bracket.

### BRIEF DESCRIPTION OF DRAWINGS

### Drawing Description

In order to more clearly illustrate the technical solutions of the embodiments of the application, the drawings illustrating the embodiments will be briefly described below. Obviously, the drawings in the following description merely illustrate some embodiments of the present invention. Other drawings may also be obtained by those skilled in the art according to these figures without paying creative work.

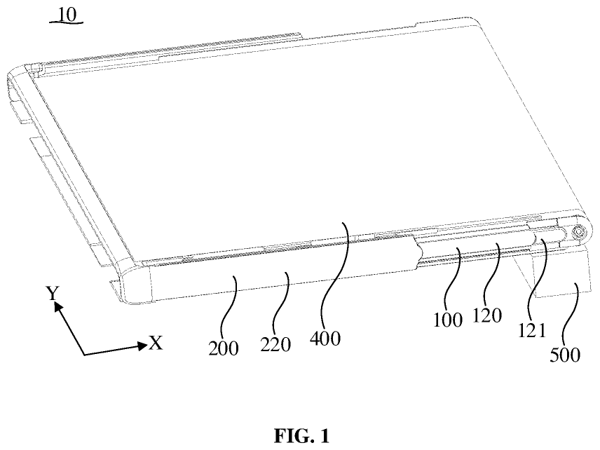

FIG. 1 is a schematic three-dimensional structure diagram of a flexible display module provided by an embodiment of the present application.

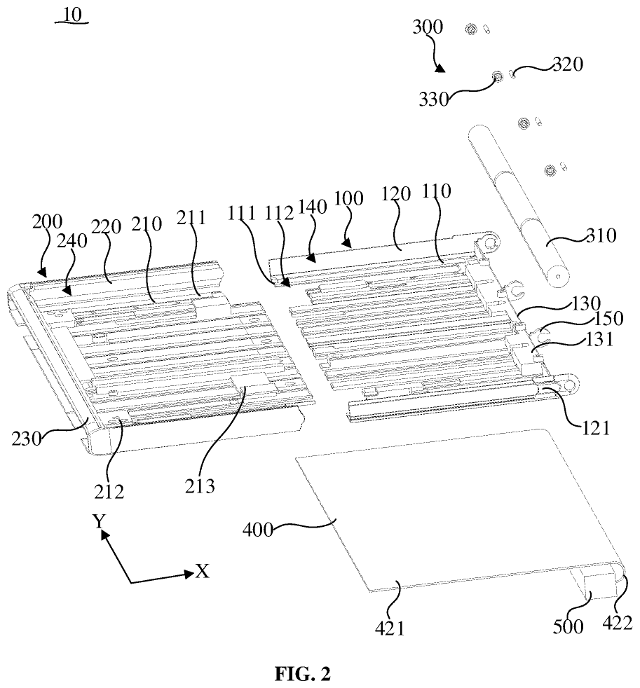

FIG. 2 is a schematic diagram of an exploded structure of a flexible display module provided by an embodiment of the present application.

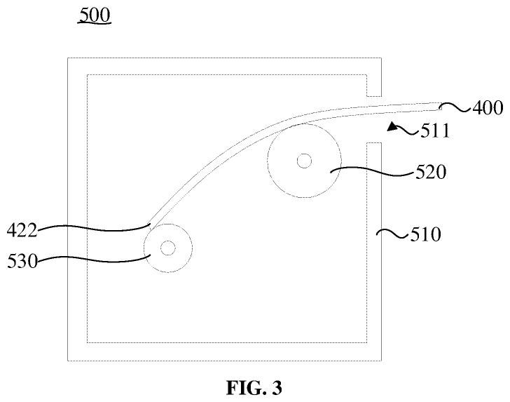

FIG. 3 is a schematic structural diagram of a winding mechanism provided by an embodiment of the present application.

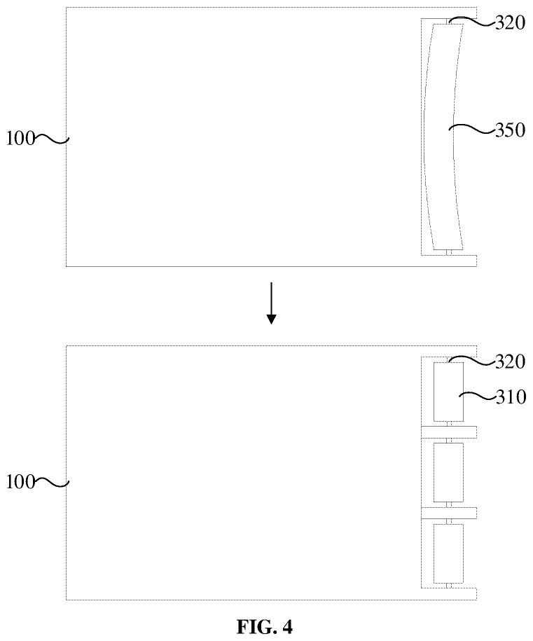

FIG. 4 is a schematic diagram of a comparison between a conventional flexible display module and a flexible display module provided by an embodiment of the present application.

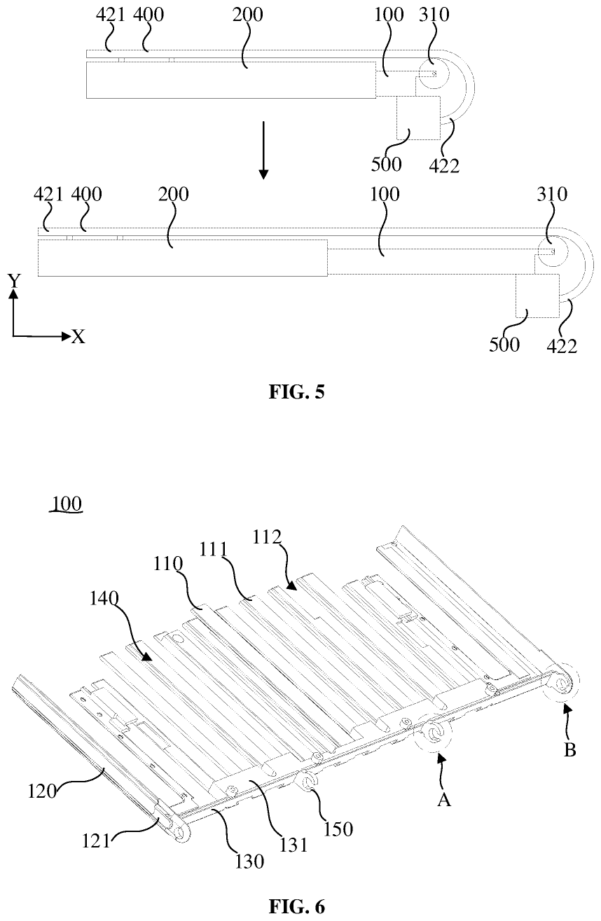

FIG. 5 is a schematic diagram of a principle of the first flexible display module provided by an embodiment of the present application;

FIG. 6 is a schematic three-dimensional structural diagram of a fixing bracket provided in an embodiment of the present application.

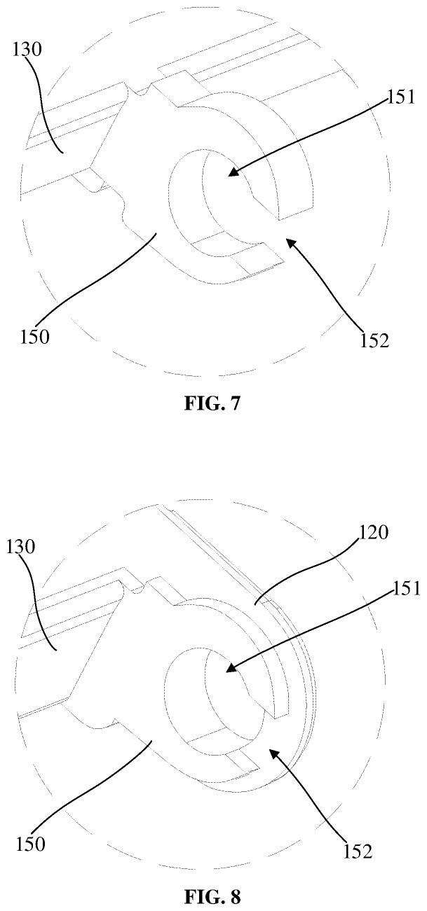

FIG. 7 is an enlarged structural representation of area A FIG. 6.

FIG. 8 is an enlarged structural representation of area B in FIG. 6.

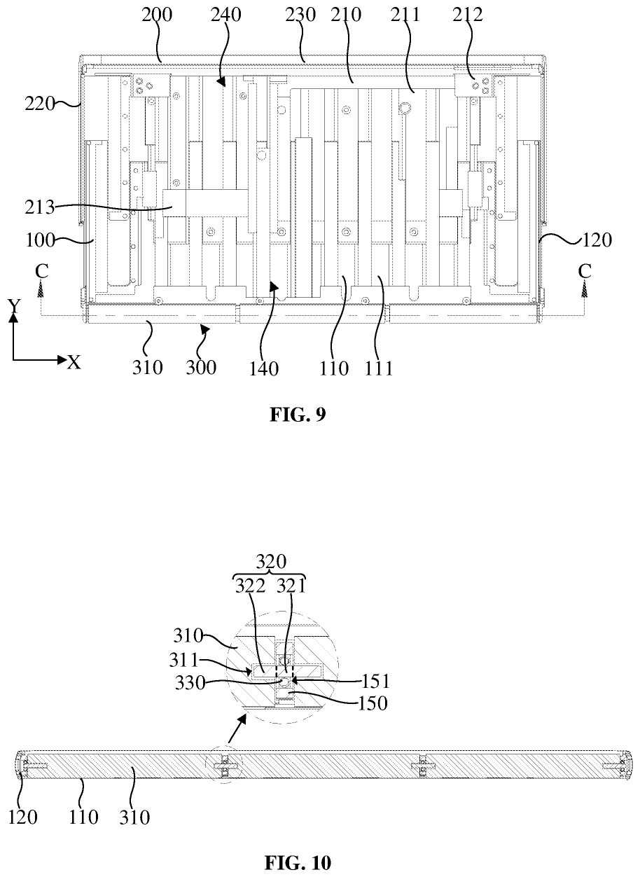

FIG. 9 is a schematic top-view structural diagram of a flexible display module provided by an embodiment of the present application.

FIG. 10 is a first sectional structure schematic diagram taken along the line C-C in FIG. 9.

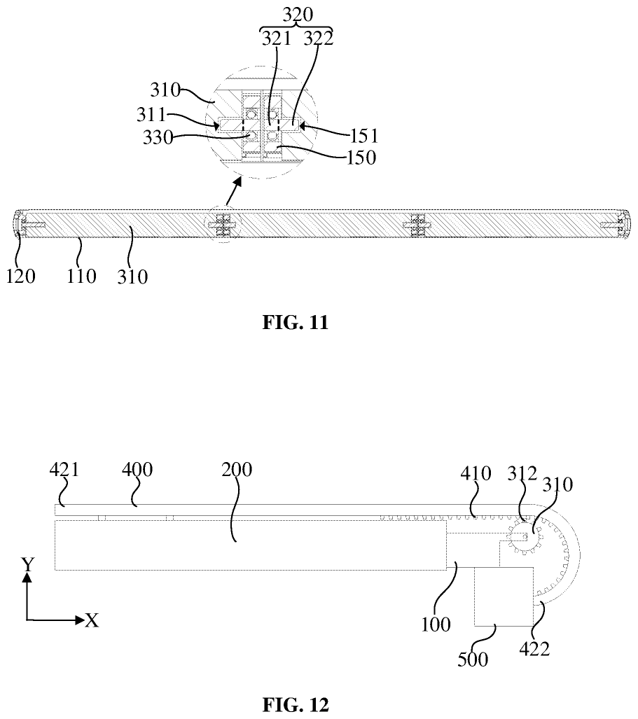

FIG. 11 is a second sectional structure schematic diagram taken along the line C-C in FIG. 9.

FIG. 12 is a second schematic diagram of a principle of a flexible display module provided by an embodiment of the present application.

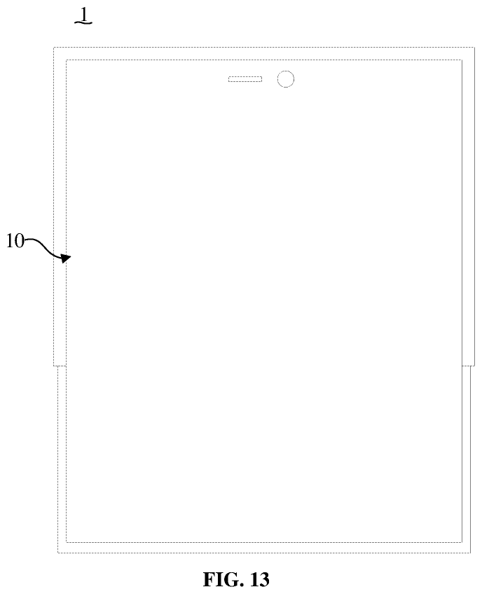

FIG. 13 is a schematic structural diagram of an electronic device provided by an embodiment of the present application.

### EMBODIMENTS OF INVENTION

### Detailed Description of Preferred Embodiments

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application. In addition, it should be understood that the specific implementations described here are only used to illustrate and explain the application, and are not used to limit the application. In the present application, unless otherwise stated, the orientation words used such as “upper” and “lower” generally refer to the upper and lower directions of the device in actual use or working state, and specifically refer to the drawing directions in the drawings, while “inner” and “outer” refer to the outline of the device.

Embodiments of the present application provide a flexible display module and an electronic device. Each of them will be described in detail below. It should be noted that the description order of the following embodiments is not intended to limit the preferred order of the embodiments.

Referring to FIGS. 1 and 2, an embodiment of the present application provides a flexible display module 10, which includes a fixing bracket 100, a middle frame bracket 200, a rolling unit 300 and a flexible display panel 400, and the middle frame bracket 200 is slidably connected to the fixing bracket 100. Specifically, the middle frame bracket 200 is slidably connected to the fixing bracket 100 along a first direction X, that is, the middle frame bracket 200 can slide along the first direction X on the fixing bracket 100.

Specifically, the rolling unit 300 is disposed on the fixing bracket 100, and the rolling unit 300 is configured to support the flexible display panel 400. The rolling unit 300 includes at least two rolling elements 310, axial directions of the at least two rolling elements 310 are parallel to each other, and the at least two rolling elements 310 are arranged in sequence along the axial directions, that is, at least two rolling elements 310 are arranged in a row. The rolling elements 310 can be, but is not limited to, a platen or a roller. Each of the rolling elements 310 is rotatably connected to the fixing bracket 100, that is, the rolling elements 310 can rotate on the fixing bracket 100. In this embodiment, at least two rolling elements 310 are arranged at intervals along the first direction X, a rotation axis 320 of each of the rolling elements 310 relative to the rotation of the fixing bracket 100 extends along a second direction Y, and the axial direction of the rolling elements 310 is parallel to the second direction Y, the first direction X is vertical to the second direction Y. Of course, according to actual situations and specific requirements, an included angle between the first direction X and the second direction Y can be adjusted appropriately. It should be noted that the above-mentioned axial direction refers to a direction along a central axis of each of the rolling elements 310.

Optionally, at least two rolling elements 310 may be coaxially arranged. It should be noted that the condition that the at least two rolling elements 310 can be coaxially arranged means that the rotation axes of the at least two rolling elements 310 that rotate relative to the fixing bracket 100 are collinear.

Specifically, a first end 421 of the flexible display panel 400 is fixedly connected to the middle frame bracket 200, and the flexible display panel 400 is partially supported on the rolling elements 310. In such a structure, when the middle frame bracket 200 slides on the fixing bracket 100, the flexible display panel 400 will also move with the middle frame bracket 200, and during the movement of the flexible display panel 400, the rolling elements 310 will also rotate, so that a back of the flexible display panel 400 is stably supported on the middle frame bracket 200 and the at least two rolling elements 310.

Specifically, both ends of each of the rolling elements 310 are supported on the fixing bracket 100, and each of the rolling elements 310 can be stably fixed on the fixing bracket 100, which can improve the reliability of the rolling elements 310.

As shown in FIG. 4, if the rolling unit 300 of the embodiment of the present application is set as a roller 350, when the middle frame bracket 200 slides on the fixing bracket 100, the flexible display panel 400 will also move with the middle frame bracket 200, and during the movement of the flexible display panel 400, the roller 350 also rotates, so that a back of the flexible display panel 400 is supported on the middle frame bracket 200 and the roller 350. Because a length of the roller 350 is relatively long, a middle of the roller 350 is suspended without any support, so the middle of the roller 350 is easily collapsed and deformed, resulting in a jam phenomenon during a rotation of the roller 350, and a sliding load of the middle frame bracket 200 is added.

In order to solve the above problems, as shown in FIG. 4, the present application adopts multi-segment rolling elements 310 to replace the rollers 350 to support the flexible display panel 400. Since a length of the rolling elements 310 is less than a length of the roller 350, and the two ends of each segment of the rolling elements 310 are supported on the fixing bracket 100, the above-mentioned rolling elements 310 are evenly stressed, the supporting strength is higher, and the rolling elements 310 is not easily deformed. As such, there is no jamming when the rolling elements 310 rotates, effectively reducing the sliding load of the middle frame bracket 200 relative to the fixing bracket 100.

Specifically, as shown in FIGS. 1 and 2, the flexible display module 10 further includes a winding mechanism 500, a second end 422 of the flexible display panel 400 is connected to the winding mechanism 500, and the winding mechanism 500 is configured to wind the flexible display panel 400. As shown in FIG. 5, when the middle frame bracket 200 moves to the left, the winding mechanism 500 releases the flexible display panel 400, and the middle frame bracket 200 drives the flexible display panel 400 to move to the left. At the same time, the rolling elements 310 rotate counterclockwise, so that the flexible display panel 400 can be smoothly unfolded. When the display screen needs to be reduced, the middle frame bracket 200 can be moved to the right, the winding mechanism 500 can rewind the flexible display panel 400, and the middle frame bracket 200 drives the flexible display panel 400 to move to the right. At the same time, the rolling elements 310 rotate clockwise, so that the flexible display panel 400 can be rolled up smoothly.

Specifically, as shown in FIG. 3, the winding mechanism 500 may include a casing 510, a roller 520 and a winding mechanism 530, the casing 510 is provided with an opening 511 for the flexible display panel 400 to pass through, and the winding mechanism 530 is provided in the casing 510, the winding mechanism 530 is configured to wind the flexible display panel 400, the roller 520 is rotatably connected to an interior of the casing 510, and the second end 422 of the flexible display panel 400 enters the interior of the casing 510 from the opening 511, and passes through the roller 520 to fixedly connect to the winding mechanism 530, so that the winding mechanism 500 can wind the flexible display panel 400. In this embodiment, the winding mechanism 530 may specifically be a coil spring or a motor.

In the flexible display module 10 of the embodiment of the present application, the rolling unit 300 includes three rolling elements 310. Of course, a number of the rolling elements 310 can be adjusted according to the actual selections and specific requirements, which is not particularly limited herein.

Specifically, as shown in FIG. 2, the rolling unit 300 further includes a plurality of rotating shafts 320 and a plurality of supporting rotating elements 330, and the axial direction of the rotating shafts 320 and the axial direction of the supporting rotating elements 330 are parallel to the axial direction of the rolling elements 310; the plurality of rotating shafts 320 are arranged in sequence along the axial direction of the rotating shafts 320, the rotating shafts 320 are fixed to the rolling elements 310; the plurality of supporting rotating elements 330 are sequentially arranged along the axial direction of the supporting rotating elements 320, each of the supporting rotating elements 320 is sleeved outside one of the rotating shafts 320, each of the supporting rotating elements 320 is disposed on the fixing bracket 100, and the rotating shafts 320 are rotatably connected to the fixing bracket 100 through the supporting rotating elements 330.

Specifically, the supporting rotating elements 330 can be a bearing. Of course, the supporting rotating elements 330 can also be other elements according to the selections and specific requirements of the actual situations. For example, the supporting rotating elements 330 can be a shaft sleeve, and the shaft sleeve is sleeved on the rotating shafts 320. In addition, a relative rotation between the shaft sleeve and the rotating shafts 320 can be achieved by lubricating oil, which is not particularly limited herein.

Specifically, as shown in FIG. 2, FIG. 6, and FIG. 7, the fixing bracket 100 is provided with a mounting seat 150, the mounting seat 150 is provided with a mounting hole 151, and the supporting rotating elements 330 are mounted in the mounting hole 151. In this structure, the mounting seat 150 is protruded from one end of the fixing bracket 100 along the first direction X, opposite ends of each of the rolling elements 310 are respectively provided with the mounting seat 150, and the two ends of each of the rolling elements 310 are respectively rotatably connected to the mounting seat 150 by corresponding ones of the rotating shafts 320 and the supporting rotating elements 330, so that the rolling elements 310 are suspended in the air, so as to realize the rotation of the rolling elements 310 relative to the fixing bracket 100.

Specifically, as shown in FIGS. 2, 6 and 7, the mounting seat 150 is further provided with a notch 152, and the notch 152 communicates with the mounting hole 151. In such a structure, during an assembling process, the rotating shafts 320 can be fixed on the rolling elements 310, the supporting rotating elements 330 can be sleeved on the rotating shafts 320, and then the supporting rotating elements 330 at both ends of the rolling elements 310 can be installed to the mounting holes 151 through the notches 152. When the rolling unit 300 needs to be repaired or replaced, each of the supporting rotating elements 330 at both ends of each of the rolling elements 310 can be pulled out through the notches 152, so that each of the supporting rotating elements 330 at both ends of each of the rolling elements 310 are separated from the mounting holes 151, which greatly improves disassembly efficiency of the rolling elements 300.

Specifically, a width of the notch 152 is smaller than a diameter of the mounting hole 151, the diameter of the mounting hole 151 matches an outer diameter of each of the supporting rotating elements 330, that is, the diameter of the mounting hole 151 is equal to the outer diameter of each of the supporting rotating elements 330, and the width of the notch 152 is less than the outer diameter of each of the supporting rotating elements 330. In such a structure, after each of the supporting rotating elements 330 is installed into the mounting hole 151, since the width of the notch 152 is smaller than the outer diameter of each of the supporting rotating elements 330, the mounting hole 151 can stably clamp the supporting rotating element 330, and the supporting rotating element 330 is not easy to disengage from the mounting hole 151. An external force is required to make the supporting rotating elements 330 open the notches 152, so that the supporting rotating element 330 can be taken out from the mounting hole 151.

Specifically, the width of the notch 152 is less than half of the diameter of the mounting hole 151, which can ensure that the supporting rotating elements 330 are stably clamped in the mounting hole 151.

Specifically, as shown in FIGS. 2 and 6, the fixing bracket 100 includes two first sidewalls 120, a second sidewall 130, and a first bottom wall 110. Opposite sides of the first bottom wall 110 are respectively connected to the first sidewalls 120, that is, one side of the first bottom wall 110 is connected with one of the first sidewalls 120, another side of the first bottom wall 110 is connected to another one of the first sidewalls 120, and the two first sidewalls 120 are disposed opposite to each other. One end of the first bottom wall 100 is connected to the second sidewall 130, one end of the second sidewall 130 is connected to one of the first sidewalls 120, and another end of the second sidewall 130 is connected to another one of the first sidewalls 120, and the two first sidewalls 120, the second sidewall 130, and the first bottom wall 120 are jointly enclosed to form a first accommodating space 140, and the first accommodating space 140 is used for placing a component, such as a control circuit board and the like. In such a structure, the overall structure of the flexible display module 10 is made more compact, which is beneficial to lightweight and thinning design.

Specifically, as shown in FIG. 2 and FIG. 6, the mounting seat 150 is provided on the second sidewall 130. Specifically, the mounting seat 150 is connected to the side of the second sidewall 130 away from the first accommodating space 140. Parts of the second sidewall 130 are provided with reinforcement portions 131. Specifically, the reinforcement portions 131 can be formed by thickening parts of the second sidewalls 130. In such a structure, the reinforcement portion 131 can improve the strength and rigidity of the second sidewall 130, so that each of the rolling elements 310 is stably supported on the mounting seat 150 of the second sidewall 130. In this embodiment, the reinforcement portion 131 is also connected to the first bottom wall 110.

Specifically, as shown in FIGS. 6 to 8, the second sidewall 130 is provided with at least two mounting seats 150, and all the mounting seats 150 are provided between the two first sidewalls 120, wherein the outermost mounting seat 150 is connected to the first sidewall 120, In such a structure, the strength and rigidity of the outermost mounting seat 150 can be increased, so that the each of rolling elements 310 is stably supported on the mounting seat 150 of the second sidewall 130.

Specifically, as shown in FIG. 2, the middle frame bracket 200 includes two third sidewalls 220, a fourth sidewall 230 and a second bottom wall 210. Opposite sides of the second bottom wall 210 are respectively connected to third sidewalls 220, that is, one side of the second bottom wall 210 is connected with one of the third sidewall 220, and another side of the second bottom wall 210 is connected with another one of third sidewall 220, and the two third sidewalls 220 are disposed opposite to each other. One end of the second bottom wall 210 is connected with a fourth sidewall 230, one end of the fourth sidewall 230 is connected with a third sidewall 220, and the other end of the fourth sidewall 230 is connected with another third sidewall 220. The two third sidewalls 220, the fourth sidewall 230 and the second bottom wall 210 are jointly enclosed to form a second accommodating space 240, and the second accommodating space 240 is used for placing components such as control circuit boards. In such a structure, an overall structure of the flexible display module 10 is made more compact, which is beneficial to the lightweight and thinning design.

Specifically, as shown in FIG. 1 and FIG. 2, the two first sidewalls 120 are located between the two third sidewalls 220, the fourth sidewall 230 is disposed opposite the second sidewall 130, and the second accommodating space 240 communicates with the first accommodating space 140. In such a structure, the overall structure of the flexible display module 10 is made more compact, which is beneficial to the lightweight and thinning design.

Specifically, as shown in FIG. 2, the first end 421 of the flexible display panel 400 is fixed on the second bottom wall 210. Specifically, the second bottom wall 210 is protruded from the fixing portion 212, and the first end 421 of the flexible display panel 400 may, but not limited to, be mounted on the fixing portion 212 by screws. In this embodiment, the second bottom wall 210 is provided with two fixing portions 212. Of course, a number of the fixing portions 212 can be appropriately adjusted according to actual selections and specific requirements, which is not particularly limited herein.

Specifically, as shown in FIG. 2, the second bottom wall 210 is further provided with a support portion 213, and the flexible display panel 400 is also supported on the support portion 213. In such a structure, the flexible display panel 400 is supported by the fixed portion 212, the support portion 213, and the rolling elements 310, making the flexible display panel 400 more flat, and there will be no middle depression. In this embodiment, the second bottom wall 210 is provided with two supporting parts 213. Of course, a number of the supporting parts 213 can be adjusted appropriately according to actual selections and specific requirements, which is not particularly limited herein.

Specifically, as shown in FIG. 2 and FIG. 6, the first bottom wall 110 includes a plurality of first ribs 111 arranged at intervals, and a gap 112 is defined between adjacent ones of the first ribs 111. The second bottom wall 210 includes a plurality of second ribs 211 arranged at intervals, and each of the second ribs 211 are inserted into the corresponding one of the gap 112. In such a structure, the overall structure of the flexible display module 10 is made more compact, which is beneficial to the lightweight and thinning design. In this embodiment, the fixing portion 212 is provided on a corresponding one of the second ribs 211, and the supporting portion 213 is provided on a corresponding one of the second ribs 211.

Specifically, as shown in FIG. 2, the first sidewall 120 is protruded with a limiting portion 121, and the limiting portion 121 is configured to block the middle frame bracket 200. Specifically, the limiting portion 121 abuts against the third sidewall 220, thereby preventing the middle frame bracket 200 from sliding to the right and ensuring a size of a display surface of the flexible display panel 400.

Specifically, as shown in FIGS. 9 and 10, the flexible display panel 400 is omitted in FIG. 9. At least two rolling elements 310 rotate synchronously, that is, any adjacent ones of the rolling elements 310 can rotate synchronously. In such a structure, it can be ensured that the flexible display panel 400 is evenly unfolded or rewound?.

Specifically, as shown in FIG. 10, adjacent ones of the rolling elements 310 are fixedly connected to the same rotating shaft 320, so that at least two rolling elements 310 rotate synchronously. Of course, according to the actual situations and specific needs, other methods may be used to make the at least two rolling elements 310 rotate synchronously. For example, the at least two rolling elements 310 are fixedly connected to different rotating shafts, and the different rotating shafts are connected to each other by gears or other transmission modes, so that the at least two rolling elements 310 rotate synchronously, which is not particularly limited herein.

In another embodiment of the present application, as shown in FIG. 9 and FIG. 11, at least two rolling elements can rotate independently. In such a structure, each of the rolling elements 310 can rotate independently, and adjacent ones of the rolling elements 310 will not interfere with each other, so that the force of each of the rolling elements 310 is uniform. When the middle frame bracket 200 slides relative to the fixing bracket 100 to unfold or rewind the flexible display panel 400, each of the rolling elements 310 will rotate, but the adjacent ones of the rolling elements 310 will not interfere with each other. Therefore, the flexible display panel 400 can be unfolded or rewound normally.

Specifically, as shown in FIG. 11, at least two rolling elements 310 are fixedly connected to different rotating shafts 320 respectively, the rotating shafts 320 are in one-to-one correspondence with the supporting rotating elements 330, and each of the rolling elements 310 is rotatably connected to the fixing bracket 100 through corresponding ones of the rotating shafts 320 and the supporting rotating elements 330, that is, among adjacent ones of the rolling elements 310, one of the rolling elements 310 is fixedly connected to one of the rotating shafts 320, and another one of the rolling elements 310 is fixedly connected to another one of the rotating shafts 320. Of course, other methods may be used to make the at least two rolling elements 310 rotate separately and independently according to the actual situations and specific requirements, which is not particularly limited herein.

Specifically, as shown in FIG. 10 and FIG. 11, the rotating shafts 320 includes a first segment 321 and a second segment 322, the first segment 321 is connected with the second segment 322, the first segment 321 is configured to connect and support the rotating element 330, and the first segment 321 is configured to connect and support the rotating element 330. The second segment 322 is configured to fixedly connect the rolling element 310. Specifically, the supporting rotating element 330 is sleeved outside the first segment 321, so that the rotating shaft 320 is rotatably connected to the fixing bracket 100 through the supporting rotating element 330. Specifically, each of the rolling elements 310 is provided with a fixing hole 311, and the second segment 322 is inserted into the fixing hole 311, so that each of the rolling elements 310 is fixedly connected to a corresponding one of the rotating shafts 320, so that the rolling elements 310 and the corresponding rotating shafts 320 can rotate synchronously. In this embodiment, the second segment 322 can be fixed in the fixing hole 311 by but not limited to interference fit and adhesive bonding.

In one embodiment, as shown in FIG. 10, the rotating shafts 320 includes a first segment 321 and two second segments 322, one end of the first segment 321 is connected to one of the second segments 322, and another end of the first segment 321 is connected to another one of the second segments 322. In such a structure, among the adjacent ones of the rolling elements 310, one of the rolling elements 310 is fixedly connected to the second segment 322 at one end of the corresponding one of the rotating shafts 320, and another one of the rolling elements 310 is fixedly connected to another end of the same one of the rotating shafts 320. The second segment 322 enables adjacent ones of the rolling elements 310 to be fixedly connected to the same one of the rotating shafts 320, so that all the rolling elements 310 can rotate synchronously.

In another embodiment, as shown in FIG. 11, each of the rotating shafts 320 includes a first segment 321 and a second segment 322, and one end of the first segment 321 is connected to the second segment 322. In such a structure, among adjacent ones of the rolling elements 310, one of the rolling elements 310 is fixedly connected to the second segment 322 of one of the rotating shafts 320, and another one the rolling elements 310 is fixedly connected to the second segment 322 of another one of the rotating shafts 320, so that adjacent ones of the rolling elements 310 are fixedly connected to different rotating shafts 320, so that each of the rolling elements 310 can rotate and operate independently. In this embodiment, since each rolling element 310 can rotate independently, when the flexible display panel 400 contacts the rolling element 310 and is displaced, each of the rolling elements 310 can generate different rotation angles, so as to better match displacement of the flexible display panel 400.

Specifically, a shape of the fixing hole 311 is adapted to a shape of the second segment 322, that is, a shape of the fixing hole 311 is the same as a shape of the second segment 322, and a cross-sectional shape of the second segment 322 can be circular. Of course, in order to increase an interlocking strength between the rotating shafts 320 and the rolling elements 310, the cross-sectional shape of the second segment 322 can also be in the shape of an ellipse, a triangle, a quadrilateral, or a pentagon. It should be noted that the above-mentioned cross-sectional shape refers to a cross-sectional shape cut by a plane perpendicular to the rotating shafts 320.

Specifically, as shown in FIG. 12, the circumferential surfaces of the rolling elements 310 are provided with a plurality of gear teeth 312, the back of the flexible display panel 400 is provided with a rack 410, and the gear teeth 312 are engaged and connected to the rack 410. In such a structure, the matching accuracy between the rolling elements 310 and the flexible display panel 400 can be improved, so as to control the movement of the flexible display panel 400 and prevent the flexible display panel 400 from slipping on the rolling elements 310.

Referring to FIG. 13, an embodiment of the present application further provides an electronic device 1 including the flexible display module 10 as described above. The electronic device 1 may be a mobile terminal, such as a smart phone, a tablet computer, a notebook computer, etc., and the electronic device 1 may also be a wearable terminal, such as a smart watch, a smart bracelet, a smart glasses, an augmented reality device, etc. The electronic device 1 can also be a fixed terminal, such as a desktop computer, a TV, etc.

A flexible display module and an electronic device provided by the embodiments of the present application have been introduced in detail above. Specific examples are used to explain the principle and implementation of the present application. The descriptions of the above embodiments are only used to help understand the present application. Also, for those skilled in the art, according to the ideas of the present application, there will be changes in the specific implementation and application scope. In summary, the content of this specification should not be construed as limiting the present application.

What is claimed is:

1. A flexible display module, comprising:
a fixing bracket;
a middle frame bracket slidably connected to the fixing bracket;
a rolling unit disposed on the fixing bracket, wherein the rolling unit comprises at least two rolling elements, axial directions of the at least two rolling elements are parallel to each other, and the at least two rolling elements are arranged in sequence along the axial directions, each of the rolling elements is rotatably connected to the fixing bracket, and both ends of each of the rolling elements are supported on the fixing bracket;
a flexible display panel, wherein a first end of the flexible display panel is fixedly connected to the middle frame bracket, and the flexible display panel is partially supported on the rolling elements; and
a winding mechanism, wherein a second end of the flexible display panel is connected to the winding mechanism, and the winding mechanism is configured to wind the flexible display panel.

2. The flexible display module according to claim 1, wherein the at least two rolling elements are disposed coaxially.

3. The flexible display module according to claim 2, wherein the rolling unit further comprises a plurality of rotating shafts and a plurality of supporting rotating elements, an axial direction of the rotating shafts and an axial direction of the supporting rotating elements are parallel to the axial directions of the rolling elements; the plurality of rotating shafts are arranged in sequence along the axial direction of the rotating shafts, the rotating shafts are fixed to the rolling elements; the plurality of supporting rotating elements are sequentially arranged along the axial direction of the supporting rotating elements, each of the supporting rotating elements is sleeved outside one of the rotating shafts, each of the supporting rotating elements is disposed on the fixing bracket, and the rotating shafts is rotatably connected to the fixing bracket through the supporting rotating elements.

4. The flexible display module according to claim 3, wherein the fixing bracket is provided with a mounting seat, the mounting seat is provided with a mounting hole, and each of the supporting rotating elements is mounted in the mounting hole.

5. The flexible display module according to claim 4, wherein the mounting seat is further provided with a notch, and the notch communicates with the mounting hole.

6. The flexible display module according to claim 5, wherein a width of the notch is smaller than a diameter of the mounting hole.

7. The flexible display module according to claim 3, wherein the at least two rolling elements rotate synchronously.

8. The flexible display module according to claim 7, wherein adjacent ones of the rolling elements are fixedly connected to a same one of the rotating shafts.

9. The flexible display module according to claim 3, wherein the at least two rolling elements are capable of rotating independently.

10. The flexible display module according to claim 9, wherein the at least two rolling elements are respectively fixedly connected to different rotating shafts, and the rotating shafts are in one-to-one correspondence to the supporting rotating elements, and each of the rolling elements is rotatably connected to the fixing bracket through a corresponding one of the rotating shafts and a corresponding one of the supporting rotating elements.

11. The flexible display module according to claim 1, wherein the fixing bracket comprises two first sidewalls, a second sidewall, and a first bottom wall, opposite sides of the first bottom wall are respectively connected to the first sidewalls, one end of the first bottom wall is connected to the second sidewall, one end of the second sidewall is connected to one of the first sidewalls, and another end of the second sidewall is connected to another one of the first sidewalls, and the two first sidewalls, the second sidewall, and the first bottom wall are jointly enclosed to form a first accommodating space.

12. The flexible display module according to claim 11, wherein the middle frame bracket comprises two third sidewalls, a fourth sidewall, and a second bottom wall, opposite sides of the second bottom wall are respectively is connected to the third sidewalls, one end of the second bottom wall is connected to the fourth sidewall, one end of the fourth sidewall is connected to one of the third sidewalls, another end of the fourth sidewall is connected to another one of the third sidewalls, and the two third sidewalls, the fourth sidewall, and the second bottom wall are jointly enclosed to form a second accommodating space; and
wherein the two first sidewalls are located between the two third sidewalls, the fourth sidewall and the second sidewall are arranged opposite to each other, and the second accommodating space communicates with the first accommodating space.

13. The flexible display module according to claim 12, wherein a fixing portion is protruded from the second bottom wall, and the first end of the flexible display panel is mounted on the fixing portion.

14. The flexible display module according to claim 12, wherein the second bottom wall is further provided with a support portion, and the flexible display panel is supported on the support portion.

15. The flexible display module according to claim 1, wherein a plurality of gear teeth are arranged on circumferential surfaces of the rolling elements, a back of the flexible display panel is provided with a rack, and the gear teeth are engaged and connected to the rack.

16. An electronic device, comprising the flexible display module according to claim 1.

17. The electronic device according to claim 16, wherein the at least two rolling elements are disposed coaxially.

18. The electronic device according to claim 17, wherein the rolling unit further comprises a plurality of rotating shafts and a plurality of supporting rotating elements, an axial direction of the rotating shafts and an axial direction of the supporting rotating elements are parallel to the axial directions of the rolling elements; the plurality of rotating shafts are arranged in sequence along the axial direction of the rotating shafts, the rotating shafts are fixed to the rolling elements; the plurality of supporting rotating elements are sequentially arranged along the axial direction of the supporting rotating elements, each of the supporting rotating elements is sleeved on an outside of one of the rotating shafts, each of the supporting rotating elements is disposed on the fixing bracket, and the rotating shafts is rotatably connected to the fixing bracket through the supporting rotating elements.

19. The electronic device according to claim 18, wherein the fixing bracket is provided with a mounting seat, the mounting seat is provided with a mounting hole, and each of the supporting rotating elements is mounted in the mounting hole.

20. The electronic device according to claim 19, wherein the mounting seat is further provided with a notch, and the notch communicates with the mounting hole.
